(19) United States
(12) Patent Application Publication
(10) Pub. No.: US 2026/0101672 A1
(43) Pub. Date: Apr. 9, 2026

(54) DEVICE AND METHODS FOR AN INTEGRATED HAPTIC DRIVER

(71) Applicant: Microchip Technology Incorporated, Chandler, AZ (US)

(72) Inventor: Razvan Costache, Dambovita (RO)

(73) Assignee: Microchip Technology Incorporated, Chandler, AZ (US)

(21) Appl. No.: 18/983,442

(22) Filed: Dec. 17, 2024

Related U.S. Application Data
(60) Provisional application No. 63/703,400, filed on Oct. 4, 2024.

(51) Int. Cl. H10N 30/80; H03K 3/017; H03K 17/687; H10N 30/20

(52) U.S. Cl. CPC H10N 30/802; H03K 3/017; H03K 17/687; H10N 30/20

(57) ABSTRACT

A device for driving a haptic actuator includes a driver circuit, a boost converter, a power device and a discharge circuit. In operation, an input signal may be converted into a PWM signal in the driver circuit. The PWM signal may drive the power device and the boost converter may generate an increasing amplitude at a high-voltage output. The discharge circuit may discharge the voltage on the high-voltage output and may decrease the amplitude at the high-voltage output.

### PRIORITY

This application claims priority to commonly owned United States Provisional Patent 63/703,400 filed on October 4, 2024, the entire contents of which are hereby incorporated by reference for all purposes.

### FIELD OF THE INVENTION

The present disclosure relates to a device and method for an integrated haptic driver, more specifically to a single-chip haptic driver.

### BACKGROUND

In haptic applications, including but not limited to those utilizing piezoelectric actuators, multiple discrete semiconductor devices may be used to produce the desired voltage and current to drive the actuator. In one of various examples, a haptic system may include a microcontroller or microprocessor to generate a digital signal, a digital-to-analog converter (DAC) to convert the digital signal to an analog signal, a PWM modulator to convert the analog signal into a PWM-modulated signal, and a power device to drive the actuator. Additionally, multiple feedback paths may exist between individual components. Such solutions may have increased costs and may operate at low efficiencies.

There is a need for devices and methods which enable an integrated haptic driver.

### SUMMARY

The examples herein enable a system and method for an integrated haptic driver.

According to one aspect, a device includes a driver circuit to receive an input signal, the driver circuit to generate a gate drive signal to a power device. The device includes a boost converter circuit coupled to the power device, the boost converter circuit generates a high-voltage output based on the gate drive signal to the power device. The device includes a haptic actuator coupled to the high-voltage output and a discharge circuit coupled to the high-voltage output. The driver circuit generates the gate drive signal and charges the high-voltage output during periods of increasing input signal. The discharge circuit discharges the high-voltage output during periods of decreasing input signal, and the driver circuit controls the discharge circuit based on a discharge drive signal, the discharge drive signal based at least on an output of a comparator. The comparator receives input from a first feedback signal and a second feedback signal.

According to one aspect, a system includes a microcontroller to generate an input signal. The system includes a single-chip haptic driver to receive the input signal, the single-chip haptic driver including a driver circuit to receive the input signal. The driver circuit generates a gate drive signal to a power device. The system includes a boost converter circuit coupled to the power device, the boost converter circuit to generate a high-voltage output based on the gate drive signal to the power device. The system includes a haptic actuator coupled to the high-voltage output and a discharge circuit coupled to the high-voltage output. The driver circuit generates the gate drive signal and charges the high-voltage output during periods of increasing input signal. The discharge circuit discharges the high-voltage output during periods of decreasing input signal. The driver circuit controls the discharge circuit based on a discharge drive signal, the discharge drive signal may be based at least on an output of a comparator, the comparator to receive input from a first feedback signal and a second feedback signal.

According to one aspect, a method includes steps of: coupling a haptic actuator to a driver circuit, receiving an input signal at the driver circuit, generating, in the driver circuit, a gate drive signal to a boost converter, the boost converter to generate a high-voltage output at the haptic actuator based on the input signal, and the gate drive signal to be active during periods of increasing input signal amplitude, and discharging, in a discharge circuit, the high-voltage output at the haptic actuator, the discharge circuit active during periods of decreasing input signal amplitude.

### BRIEF DESCRIPTION OF THE DRAWINGS

FIG. 1 illustrates one of various examples of a system for driving a haptic actuator.

FIG. 2 illustrates one of various examples of a voltage signal at a boost converter output.

FIG. 3 illustrates one of various examples of current signals in a system for driving a haptic actuator.

FIG. 4 illustrates one of various examples of a driver circuit as part of a system for driving a haptic actuator.

FIG. 5 illustrates a method of driving a haptic actuator.

### DETAILED DESCRIPTION

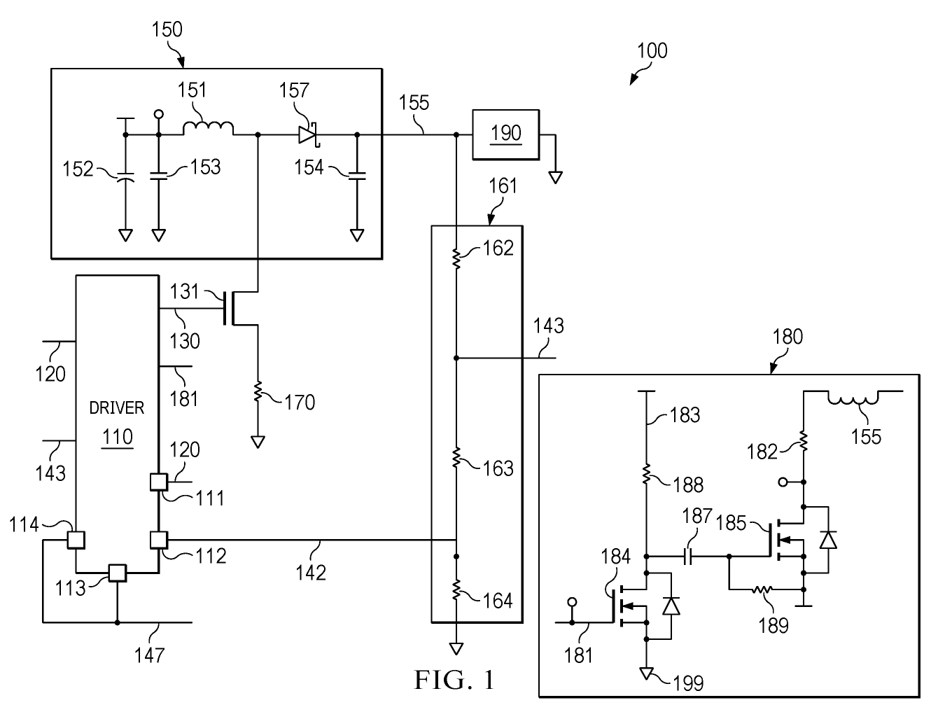

FIG. 1 illustrates one of various examples of a system 100 for driving a haptic actuator. System 100 may include a driver circuit 110. Driver circuit 110 may be an integrated device comprising a single-chip semiconductor component. Input signal 120 may be input to driver circuit 110. Input signal 120 may be a digital signal from a microcontroller or may be a digital signal from another type of digital signal source not specifically mentioned. Input signal 120 may be an analog signal from a digital-to-analog converter (DAC) or may be an analog signal from another type of analog signal source not specifically mentioned.

Input signal 120 may be a time-domain signal to generate a specific haptic response at haptic actuator 190. As one of various examples, input signal 120 may be a pulsed sinusoidal signal of a frequency between 20Hz and 1kHz, and with a duration of between 50 msec and 1 second, but this is not intended to be limiting.

Haptic actuator 190 may be a piezoelectric actuator or another type of actuator not specifically mentioned. Driver circuit 110 may include data converters, amplifiers, logic circuits, PWM modulators, clocking circuits and other circuits not specifically mentioned.

Driver circuit 110 may generate boost PWM signal 130 based at least on input signal 120. Boost PWM signal 130 may drive power device 131. Boost PWM signal 130 may be a gate drive signal to power device 131. Driver circuit 110 may include a PWM modulator to generate Boost PWM signal 130. Boost PWM signal 130 may be a PWM modulated signal.

In one of various examples, power device 131 may be a metal-oxide semiconductor field-effect transistor (MOSFET). In other examples, power device 131 may be another type of transistor or semiconductor device.

Boost converter circuit 150 may include inductor 151. Boost converter circuit 150 may include capacitors 152, 153 and 154. Boost converter circuit 150 may include diode 157. The circuit configuration of boost converter circuit 150 illustrated in FIG. 1 is for illustrative purposes and should not be taken as limiting. In other examples, another circuit configuration of boost converter circuit 150 may include a different configuration of inductors and capacitors and may include additional active or passive elements or may remove active or passive elements from the example illustrated in FIG. 1.

Boost converter circuit 150 may generate a high-voltage output 155 based on the switching behavior of boost PWM signal 130 driving power device 131. When boost PWM signal 130 is at a low voltage, power device 131 is switched off, and the current through inductor 151 may flow to haptic actuator 190 and the voltage at high-voltage output 155 may increase. In one of various examples, high-voltage output 155 may be a signal in excess of 100V peak-to-peak. The example illustrated in FIG. 1 includes an NMOS power device 131, but this is not intended to be limiting. In other examples, a PMOS power device may be included, and in these other examples, the voltage at high-voltage output 155 may increase when boost PWM signal 130 is at a high voltage.

In one of various examples, high-voltage output 155 may be at a voltage level greater than the voltage level of input signal 120. The maximum amplitude of high-voltage output 155 may be greater than the maximum amplitude of input signal 120.

Resistor divider 161 may generate output feedback signal 142. In the example illustrated in FIG. 1, resistor divider 161 includes resistor 162, resistor 163 and resistor 164, but this is not intended to be limiting. Resistor divider 161 may generate reference feedback signal 143.

Input signal 120 may be coupled to positive feedback input 111 of driver circuit 110. Positive feedback input 111 may be coupled to a non-inverting input of a comparator within driver circuit 110. Output feedback signal 142 may be coupled to negative feedback input 112 of driver circuit 110. Negative feedback input 112 may be coupled to an inverting input of a comparator within driver circuit 110. The comparator within driver circuit 110 may a be coupled to positive feedback input 111 and a signal coupled to negative feedback input 112 and may generate PWM feedback signal 147 at comparator output 113.

In operation, PWM feedback signal 147 may be input to driver circuit 110 at discharge control input 114. Circuitry in driver circuit 110 may receive input from discharge control input 114 and may, based at least on the signal at discharge control input 114, control boost PWM signal 130 and discharge drive signal 181.

Discharge circuit 180 may control the discharge of high-voltage output 155. Discharge circuit 180 may include a first discharge device 184 and a second discharge device 185. Power supply 183 may provide power to discharge circuit 180. First resistor 188 may be coupled between power supply 183 and first discharge device 184. First capacitor 187 may be coupled between first discharge device 184 and second discharge device 185. Second resistor 189 may be coupled between a gate node of second discharge device 185 and a ground node 199. Third resistor 182 may be coupled between high-voltage output 155 and second discharge device 185.

In one of various examples, first discharge device 184 may be a MOSFET device. In other examples, first discharge device 184 may be another type of transistor or semiconductor device. In one of various examples, second discharge device 185 may be a MOSFET device. In other examples, second discharge device 185 may be another type of transistor or semiconductor device. The circuit configuration of discharge circuit illustrated in FIG. 1 is for illustrative purposes and should not be taken as limiting.

Driver circuit 110 may generate discharge drive signal 181. Discharge circuit 180 may control the discharge of high-voltage output 155 based on discharge drive signal 181. Discharge drive signal 181 may be coupled to a gate node of first discharge device 184. An output of first discharge device 184 may be coupled to a node of second discharge device 185 through first capacitor 187. In this manner, discharge circuit 180 may discharge voltage on high-voltage output 155 through second discharge device 185. First discharge device 184 may discharge voltage to power supply 183 to preserve power in the system.

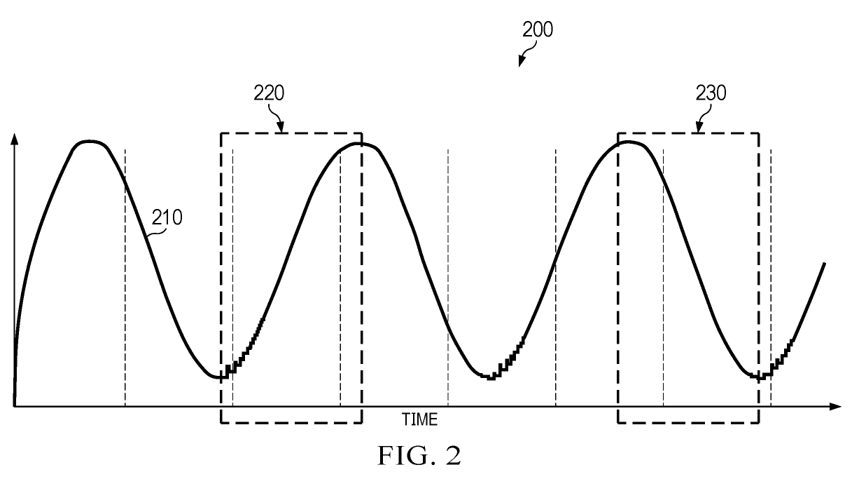

FIG. 2 illustrates one of various examples of a waveform 200 of a voltage signal at a boost converter output. Voltage signal 210 may represent one of various examples of high-voltage output 155 of boost converter circuit 150 as described and illustrated in reference to FIG. 1.

Voltage signal 210 is illustrated as a sinusoid, but this is not intended to be limiting. Voltage signal 210 may be a voltage signal in excess of 100 Volts peak-to-peak. Region 220 may illustrate a region of increasing voltage. In operation, voltage signal 210 in region 220 may be generated by a system as described and illustrated in reference to FIG. 1. In operation, power device 131 may be switched off, and the current through inductor 151 may flow to haptic actuator 190 and the voltage at high-voltage output 155 may increase. The voltage at high-voltage output 155 charged by boost converter circuit 150 may be represented by voltage signal 210 in region 220.

Region 230 may illustrate a region of decreasing voltage. In operation, voltage signal 210 in region 230 may be generated by a system as described and illustrated in reference to FIG. 1. Second discharge device 185 may be switched on, and current through may flow through second discharge device 185 and may discharge high-voltage output 155. The voltage at high-voltage output 155 may decrease. The voltage at high-voltage output 155 discharged by second discharge device 185 may be represented by voltage signal 210 in region 220.

The frequency, amplitude and shape of voltage signal 210 illustrated in FIG. 2 is for illustrative purposes and should not be taken as limiting. Voltage signal 210 may be of a different frequency, amplitude and shape than that illustrated in FIG. 2.

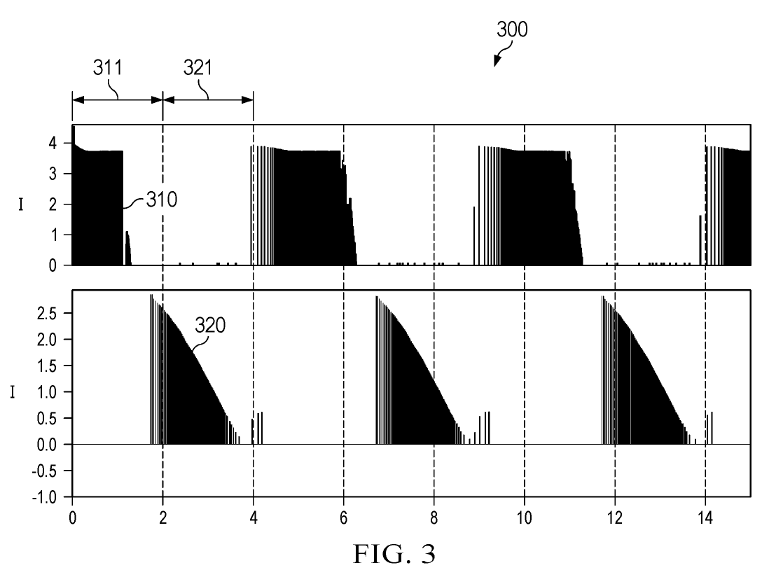

FIG. 3 illustrates one of various examples of current signals 300 in a system for driving a haptic actuator.

Current signal 310 may represent one of various examples of a current from boost converter circuit 150 as described and illustrated in reference to FIG. 1. Current signal 310 may be active during increasing voltage at high-voltage output 155. Current signal 310 may be active while power device 131 may be switched off, and may represent the current flow through inductor 151 to haptic actuator 190 and the voltage at high-voltage output 155 may increase. Time period 311 may represent one of various examples of current flow during region 220 as described and illustrated in reference to FIG. 2.

Current signal 320 may represent a discharge current through second discharge device 185 as described and illustrated in reference to FIG. 1. Current signal 320 may be active while first discharge device 184 may be switched on, and may represent the current flow through second discharge device 185 and may discharge high-voltage output 155 and result in decreasing voltage at high-voltage output 155. Time period 321 may represent one of various examples of current flow during region 230 as described and illustrated in reference to FIG. 2.

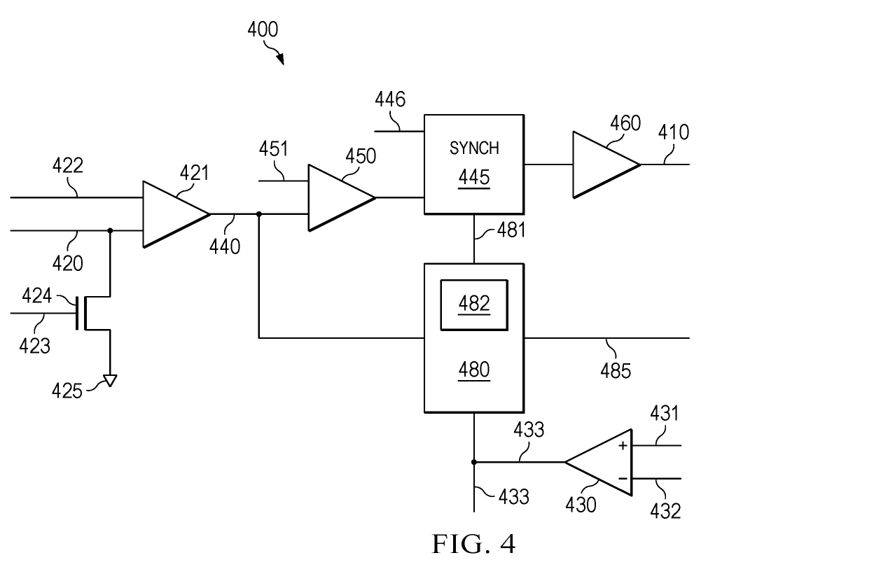

FIG. 4 illustrates one of various examples of a driver circuit 400 as part of a system for driving a haptic actuator. Driver circuit 400 may be one of various examples of driver circuit 110 as described and illustrated in reference to FIG. 1. Driver circuit 110 may include other circuits not illustrated in FIG. 4.

Haptic input signal 420 may be input to driver circuit 400. Reference signal 422 may be coupled to a first input of error amplifier 421. In one of various examples, reference signal 422 may be coupled to reference feedback signal 143 as described and illustrated in reference to FIG. 1. In other examples, reference signal 422 may be provided by an amplifier circuit, a digital-to-analog converter, a sensor or another type of circuit not specifically mentioned. Haptic input signal 420 may be coupled to a second input of error amplifier 421.

Reset device 424 may be coupled to haptic input signal 420. Reset signal 423 may be coupled to a gate node of reset device 424. In operation, an active high level on reset signal 423 may turn on reset device 424 and may place driver circuit 400 in a reset state.

An output 440 of error amplifier 421 may be input to PWM amplifier 450. A reference signal 451 may be coupled to a first input of PWM amplifier 450. Reference signal 451 may be provided by an amplifier circuit, a digital-to-analog converter, a sensor or another type of circuit not specifically mentioned. Reference signal 451 may be a ramp signal, a sinusoidal signal, a sawtooth signal, or another type of signal not specifically mentioned. Output 440 of error amplifier 421 may be coupled to a second input of PWM amplifier 450. PWM amplifier 450 may generate an output based on reference signal 451 and output 440 of error amplifier 421.

An output of PWM amplifier 450 may be input to synchronization circuit 445. Synchronization signal 446 may be coupled to synchronization circuit 445. Synchronization signal 446 may be a clock signal. Synchronization signal 446 may represent a bus of multiple signals, including but not limited to a clock signal, an error condition signal, a reset signal, or another type of signal not specifically mentioned. Control bus 481 may be coupled to synchronization circuit 445 and may be coupled to discharge control circuit 480. Control bus 481 may be a bi-directional bus and may transmit one of more signals from synchronization circuit 445 to discharge control circuit 480 and may transmit one or more signals from discharge control circuit 480 to synchronization circuit 445. Overvoltage signal 175 may be one of various examples of signals comprising control bus 481.

An output of synchronization circuit 445 may drive buffer 460. Buffer 460 may generate gate drive signal 410. Gate drive signal 410 may be one of various examples of boost PWM signal 130 as described and illustrated in reference to FIG. 1. In one of various examples, gate drive signal 410 may drive a gate node of power device 131.

Comparator 430 may amplify a difference between a first feedback signal 431 and a second feedback signal 432 and may generate comparator output 433. In one of various examples, first feedback signal 431 may be haptic input signal 420. In one of various examples, second feedback signal 432 may be output feedback signal 142 as described and illustrated in reference to FIG. 1. Comparator output 433 may be input to discharge control circuit 480. Comparator output 433 may be one of various examples of PWM feedback signal 147 as described and illustrated in reference to FIG. 1.

First feedback signal 431 may be coupled to a non-inverting input of comparator 430. Second feedback signal 432 may be coupled to an inverting input of comparator 430.

Discharge control circuit 480 may be coupled to output 440 of error amplifier 421. Discharge control circuit 480 may generate discharge drive signal 485. Discharge drive signal 485 may be one of various examples of discharge drive signal 181 as described and illustrated in reference to FIG. 1. Discharge drive signal 485 may drive a discharge circuit 180 as described and illustrated in reference to FIG. 1.

Comparator output 433 may be an output of comparator 430. Comparator output 433 may be input to discharge control circuit 480. Discharge control circuit 480 may include overlap circuit 482. Overlap circuit 482 may generate one of more signals on control bus 481. In operation, during periods of increasing voltage at high-voltage output 155, overlap circuit 482 may operate such that synchronization circuit may be active and may drive buffer 460, and discharge control circuit 480 may de-assert discharge drive signal 485 based on the value of comparator output 433. In operation, during periods of decreasing voltage at high-voltage output 155, overlap circuit 482 may operate such that synchronization circuit may be inactive and discharge control circuit 480 may assert discharge drive signal 485 based on the value of comparator output 433, discharge control circuit 480 to generate discharge drive signal 485 to decrease the voltage at high-voltage output 155. In this manner, the overlap circuit 482 may prevent simultaneous operation of the synchronization circuit to increase the voltage at high-voltage output 155 and of the discharge circuit 180 to decrease the voltage to high-voltage output 155. Such simultaneous operation of the synchronization circuit to increase the voltage at high-voltage output 155 and of the discharge circuit 180 to decrease the voltage to high-voltage output 155 may result in excess current flow in driver circuit 400 and may cause damage to driver circuit 400 and to other circuits coupled to driver circuit 400.

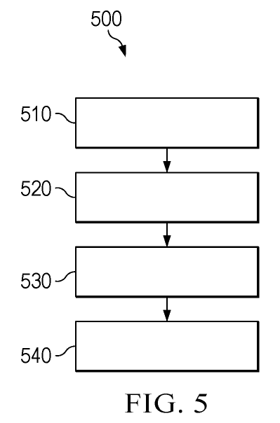

FIG. 5 illustrates a method of driving a haptic actuator.

At operation 510, a haptic actuator may be coupled to a driver circuit.

At operation 520, an input signal may be received at the driver circuit.

At operation 530, the driver circuit may generate a gate drive signal to a boost converter, the boost converter to generate a high-voltage output at an output node based on the input signal, the boost converter active during increasing periods of the input signal. The output node may be coupled to the haptic actuator.

At operation 540, a discharge circuit may discharge voltage on the output node based on the input signal. The discharge circuit may be active during decreasing periods of the input signal.

We claim:

1. A device comprising:
a driver circuit to receive an input signal, the driver circuit to generate a gate drive signal to a power device;
a boost converter circuit coupled to the power device, the boost converter circuit to generate a high-voltage output based on the gate drive signal to the power device;
a haptic actuator coupled to the high-voltage output;
a discharge circuit coupled to the high-voltage output; and
wherein the driver circuit to generate the gate drive signal and to charge the high-voltage output during periods of increasing input signal and the discharge circuit to discharge the high-voltage output during periods of decreasing input signal, and wherein the driver circuit to control the discharge circuit based on a discharge drive signal, the discharge drive signal based at least on an output of a comparator, the comparator to receive input from a first feedback signal and a second feedback signal.

2. The device as claimed in claim 1, the driver circuit comprising a PWM modulator and the gate drive signal comprising a PWM modulated signal.

3. The device as claimed in claim 1, the boost converter circuit to generate the high-voltage output of a voltage level greater than the input signal voltage level.

4. The device as claimed in claim 1, the haptic actuator comprising a piezoelectric actuator.

5. The device as claimed in claim 1, the discharge circuit comprising a first discharge device and a second discharge device, a gate node of the first discharge device coupled to the discharge drive signal, a gate node of the second discharge device coupled to an output of the first discharge device, and an output of the second discharge device coupled to the high-voltage output.

6. The device as claimed in claim 5, the first discharge device and the second discharge device comprising metal-oxide semiconductor field-effect transistors (MOSFETs).

7. The device as claimed in claim 1, an output of the comparator coupled to an overlap circuit, the overlap circuit to prevent simultaneous operation of the driver circuit and the discharge circuit.

8. The device as claimed in claim 1, the first feedback signal to be coupled to the input signal and to be coupled to a non-inverting input of the comparator and the second feedback signal to be resistively coupled to the high-voltage output and to be input to an inverting input of the comparator.

9. The device as claimed in claim 1, the comparator and the driver circuit comprising a single semiconductor device.

10. A system comprising:
a microcontroller to generate an input signal;
a single-chip haptic driver to receive the input signal, the single-chip haptic driver comprising:
a driver circuit to receive the input signal, the driver circuit to generate a gate drive signal to a power device;
a boost converter circuit coupled to the power device, the boost converter circuit to generate a high-voltage output based on the gate drive signal to the power device;
a haptic actuator coupled to the high-voltage output;
a discharge circuit coupled to the high-voltage output; and
wherein the driver circuit to generate the gate drive signal and to charge the high-voltage output during periods of increasing input signal and the discharge circuit to discharge the high-voltage output during periods of decreasing input signal, and wherein the driver circuit to control the discharge circuit based on a discharge drive signal, the discharge drive signal based at least on an output of a comparator, the comparator to receive input from a first feedback signal and a second feedback signal.

11. The system as claimed in claim 10, the driver circuit comprising a PWM modulator and the gate drive signal comprising a PWM modulated signal.

12. The system as claimed in claim 10, the boost converter circuit to generate the high-voltage output of greater than the input signal.

13. The system as claimed in claim 10, the haptic actuator comprising a piezoelectric actuator.

14. The system as claimed in claim 10, an output of the comparator coupled to an overlap circuit, the overlap circuit to prevent simultaneous operation of the driver circuit and the discharge circuit.

15. The system as claimed in claim 10, the first feedback signal to be coupled to the input signal and to be coupled to a non-inverting input of the comparator and the second feedback signal to be resistively coupled to the high-voltage output and to be input to an inverting input of the comparator.

16. The system as claimed in claim 15, the comparator and driver circuit comprising an integrated semiconductor device.

17. A method comprising:
coupling a haptic actuator to a driver circuit;
receiving an input signal at the driver circuit;
generating, in the driver circuit, a gate drive signal to a boost converter, the boost converter to generate a high-voltage output at the haptic actuator based on the input signal, and the gate drive signal to be active during periods of increasing input signal amplitude; and
discharging, in a discharge circuit, the high-voltage output at the haptic actuator, the discharge circuit active during periods of decreasing input signal amplitude.

18. The method as claimed in claim 17, the discharge circuit comprising a first discharge device and a second discharge device, a gate node of the first discharge device coupled to a discharge drive signal, a gate node of the second discharge device coupled to an output of a first discharge device, and an output of the second discharge device coupled to the high-voltage output.

19. The method as claimed in claim 17, comprising preventing, in an overlap circuit, the generating a gate drive signal and the discharging the high-voltage output from occurring simultaneously.
